(19) United States
(12) Patent Application Publication
(10) Pub. No.: US 2024/0258454 A1
(43) Pub. Date: Aug. 1, 2024

(54) METHOD FOR REPAIRING AND INSPECTING DISPLAY DEVICE

(71) Applicant: LG Display Co., Ltd., Seoul (KR)

(72) Inventors: Sunhwa Lee, Goyang-si (KR); Jongbeom Lee, Paju-si (KR); Byunghyun Lee, Paju-si (KR); Soyi Lee, Paju-si (KR); Seeun Kim, Seoul (KR)

(73) Assignee: LG Display Co., Ltd., Seoul (KR)

(21) Appl. No.: 18/221,563

(22) Filed: Jul. 13, 2023

(30) Foreign Application Priority Data
Feb. 1, 2023 (KR) 10-2023-0013593

(51) Int. Cl. H01L 33/00; H01L 27/15

(52) U.S. Cl. CPC H01L 33/0095; H01L 27/156

(57) ABSTRACT

A method for repairing and inspecting a display device include transferring a light-emitting element onto the panel substrate; positioning the inspection substrate on the panel substrate such that the contact pins of the inspection substrate face the light-emitting element; connecting the contact pins to the light-emitting element and applying a voltage to the contact pins to identify whether or not the light-emitting element emits light and thus is defective or normal; upon determination that the light-emitting element is defective, replacing the defective light-emitting element with a normal light-emitting element; and connecting a wiring electrode to the normal light-emitting element.

### CROSS-REFERENCE TO RELATED APPLICATION

This application claims the priority of Korean Patent Application No. 10-2023-0013593 filed on Feb. 1, 2023, which is hereby incorporated by reference in its entirety.

### BACKGROUND

### Field of the Disclosure

The present disclosure relates to a repairing method and particularly to, for example, without limitation, a method for repairing and inspecting the display device.

### Description of the Background

A display device is applied to various electronic devices such as TVs, mobile phones, laptops, wearable devices, automobile and tablets. To this end, research to develop thinning, lightening, and low power consumption of the display device is continuing.

Among display devices, a light-emitting display device has a light-emitting element or a light source built therein and displays information using light generated from the built-in light-emitting element or light source. A display device including a self-light-emitting element may be implemented to be thinner than a display device with the built-in light source, and may be implemented as a flexible display device that may be folded, bent, or rolled.

The display device having the self-light-emitting element may include, for example, an organic light-emitting display device (OLED) including a light-emitting layer made of an organic material, or a micro LED display device (micro light-emitting diode display device) including a light-emitting layer made of an inorganic material. In this regard, the organic light-emitting display device does not require a separate light source. However, due to material characteristics of the organic material that is vulnerable to moisture and oxygen, a defective pixel easily occurs in the organic light-emitting display device due to an external environment. On the contrary, the micro LED display device includes the light-emitting layer made of the inorganic material that is resistant to moisture and oxygen and thus is not affected by the external environment and thus has high reliability and has a long lifespan compared to the organic light-emitting display device.

Further, the micro-LED display device is resistant to the external environment, and thus does not require a protective structure such as a sealing material, and various types of materials may be used as a material of a substrate of the device. Thus, the micro-LED display device may be thinner than the organic light-emitting display device and is more advantageous in being implemented as a flexible display device. Thus, the micro-LED display device is in the limelight as a next-generation display device.

However, the micro-LED display device requires a process of forming micro-LEDs using a separate substrate and then transferring the micro-LEDs to the display device. In this case, there is a limitation in that light-emission does not occur due to a defect in the micro-LED itself or a failure in the transfer process. Accordingly, research is being conducted on a method for repairing the display device including light-emitting elements.

The description provided in the background section should not be assumed to be prior art merely because it is mentioned in or associated with the background section. The background section may include information that describes one or more aspects of the subject technology.

### SUMMARY

Accordingly, the present disclosure is directed to a method for repairing and inspecting a display device that substantially obviates one or more of problems due to limitations and disadvantages described above.

More specifically, the present disclosure is to provide a method for repairing a display device capable of carrying out a lighting inspection and a repair process immediately after transferring a light-emitting element onto a panel substrate.

The present disclosure is also to provide a method for repairing a display device capable of omitting a redundant light-emitting element to reduce a cost.

The present disclosure is not limited to the above-mentioned and other advantages according to the present disclosure that are not mentioned may be understood based on following descriptions, and may be more clearly understood based on aspects according to the present disclosure. Further, it will be easily understood that the purposes and advantages according to the present disclosure may be realized using means shown in the claims or combinations thereof.

In an aspect of the present disclosure, a method for repairing a display device includes transferring a plurality of light-emitting element onto a panel substrate: preparing an inspection substrate having a plurality of inspecting contact units each including contact pins; positioning the inspection substrate on the panel substrate such that the contact pins of the inspection substrate face the plurality of light-emitting element: determining whether the light-emitting element is defective by connecting the contact pins to the plurality of light-emitting element; and repairing the defective light-emitting element to a normal light-emitting element.

In one implementation, the light-emitting element may include: a nitride semiconductor structure including a first semiconductor layer, an active layer disposed on the first semiconductor layer, and a second semiconductor layer disposed on the active layer: a passivation pattern disposed on an outer surface of the nitride semiconductor structure: a first electrode connected to the first semiconductor layer; and a second electrode connected to the second semiconductor layer.

In one implementation, the first electrode may be formed to be coplanar with the second electrode.

In one implementation, preparing the inspection substrate may include: providing a glass substrate: forming first metal patterns disposed on the glass substrate and extending in a line shape: forming a first inspecting passivation layer covering the first metal patterns; forming second metal patterns disposed on the first inspecting passivation layer: forming a second inspecting passivation layer covering the second metal patterns: forming third metal patterns on the second inspecting passivation layer, wherein the third metal patterns may include first and second plate patterns, wherein the first and second plate patterns are spaced apart from each other; and forming the inspecting contact units including a first inspecting contact unit and a second inspecting contact units, wherein the first inspecting contact unit may be disposed on the first plate pattern and include the contact pin connected to one electrode of the light-emitting element, wherein the second inspecting contact unit may be disposed on the second plate pattern and include the contact pin connected to the other electrode of the light-emitting element.

In one implementation, each of the first and second inspecting contact unit may include protrusion pattern, fourth metal pattern covering the protrusion pattern and contact pin disposed on an upper surface of the protrusion pattern.

In one implementation, the protrusion pattern may be of a taper shape in which a width of an upper surface thereof is smaller than a width of a bottom surface thereof.

In one implementation, wherein each first plate pattern may have an island shape surrounded with the second inspecting passivation layer, wherein each second plate pattern may have an island shape surrounded with the second inspecting passivation layer.

In one implementation, the first metal pattern and the second metal pattern may be disposed in different layers and may not overlap with each other.

In one implementation, the first metal patterns and the second metal patterns may be disposed in different layers without overlapping with each other and are alternately arranged with each other.

In one implementation, wherein determining whether the light-emitting element is defective may include, applying a voltage to the contact pins to identify whether the light-emitting element is turned on.

In one implementation, wherein repairing the defective the light-emitting element may include, removing the light-emitting element determined to be defective and replacing with the normal light-emitting element.

In one implementation, a voltage having a first polarity may be applied to the first inspecting contact unit, while a voltage having a second polarity different from the first polarity may be applied to the second inspecting contact unit.

In one implementation, the first electrode or the second electrode may have a circular shape in a top view thereof.

In another aspect of the present disclosure, a method for inspecting a display device during manufacturing process of the display device, wherein the display device may include a panel substrate, includes transferring a plurality of light-emitting element onto the panel substrate: positioning the inspection substrate on the panel substrate such that contact pins of the inspection substrate face the plurality of light-emitting element; and determining whether the light-emitting element is defective by connecting the contact pins to the plurality of light-emitting element.

According to one aspect of the present disclosure, the method for repairing the display device is capable of carrying out the lighting inspection and the repair process immediately after transferring the light-emitting element onto the panel substrate, thereby omitting the redundant light-emitting element that accounts for a significant portion of a manufacturing cost and thus reducing a production cost.

Further, according to one aspect of the present disclosure, the method for repairing the display device is capable of carrying out the lighting inspection and the repair process immediately after transferring the light-emitting element onto the panel substrate, thereby removing the defective light-emitting element.

Effects of the present disclosure are not limited to the effects mentioned above, and other effects not mentioned will be clearly understood by those skilled in the art from the descriptions below.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, that may be included to provide a further understanding of the disclosure and may be incorporated in and constitute a part of the disclosure, illustrate aspects of the disclosure and together with the description serve to explain various principles of the disclosure.

FIG. 1 is a plan view schematically illustrating a pixel of a display device according to an exemplary aspect of the present disclosure;

FIG. 2 and FIG. 3 are diagrams showing a light-emitting element according to one exemplary aspect of the present disclosure; and

FIG. 4, FIG. 5, FIG. 6, FIG. 7, FIG. 8, FIG. 9 and FIG. 10 are diagrams illustrating a method for repairing a display device according to one exemplary aspect of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Advantages and features of the present disclosure, and a method of achieving the advantages and features may become apparent with reference to exemplary aspects described later in detail together with the accompanying drawings. However, the present disclosure is not limited to the exemplary aspects as disclosed below, but may be implemented in various different forms. Thus, these aspects are set forth only to make the present disclosure sufficiently thorough and complete, and to completely inform the scope of the present disclosure to those of ordinary skill in the technical field to which the present disclosure belongs.

A shape, a size, area, a ratio, an angle, a number, etc. disclosed in the drawings for describing the aspects of the present disclosure are exemplary, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth to provide a thorough understanding of the present disclosure. However, it may be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular aspects only and is not intended to be limiting of the present disclosure. As used herein, the singular constitutes “a” and “an” are intended to include the plural constitutes as well, unless the context clearly indicates otherwise. It may be further understood that the terms “comprise”, “have” and “include”, “contain,” “constitute,” “make up of,” “formed of,” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list. In interpretation of numerical values, an error or tolerance range therein may occur even when there is no explicit description thereof.

In addition, it may also be understood that when a first element or layer is referred to as being present “on” a second element or layer, the first element may be disposed directly on the second element or may be disposed indirectly on the second element with a third element or layer being disposed between the first and second elements or layers. It may be understood that when an element or layer is referred to as being “connected to”, or “coupled to” another element or layer, it may be directly on, connected to, or coupled to the other element or layer, or one or more intervening elements or layers may be present. In addition, it may also be understood that when an element or layer is referred to as being “between” two elements or layers, it may be the only element or layer between the two elements or layers, or one or more intervening elements or layers may also be present.

Where positional relationships are described, for example, where the positional relationship between two parts is described using “on,” “over,” “under,” “above,” “below,” “beneath,” “near,” “close to,” “adjacent to,” “beside,” and “next, to,” or the like, one or more other parts may be disposed between the two parts unless a more limiting term, such as “immediate(ly),” “direct(ly),” or “close(ly)” is used. For example, when a structure is described as being positioned “on,” “over,” or “under,” “above,” “below;” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference. Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

It may be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section, the essence, sequence, order, or number of the corresponding elements should not be limited by these terms. Thus, a first element, component, region, layer or section described below could be termed a second element, component, region, layer or section, without departing from the technical idea and scope of the present disclosure.

The features of the various aspects of the present disclosure may be partially or entirely combined with each other, and may be technically associated with each other or operate with each other. The aspects may be implemented independently of each other and may be implemented together in an association relationship.

In interpreting a numerical value, the value is interpreted as including an error range unless there is no separate explicit description thereof.

For the expression that an element or layer “contacts,” “overlaps,” or the like with another element or layer, the element or layer may not only directly contact, overlap, or the like with another element or layer, but also indirectly contact, overlap, or the like with another element or layer with one or more intervening elements or layers disposed or interposed between the elements or layers, unless otherwise specified. Unless otherwise defined, all terms including technical and scientific terms used herein have the same meaning as commonly understood by one of ordinary skill in the art to which this inventive concept belongs. It may be further understood that terms, such as those defined in commonly used dictionaries, may be interpreted as having a meaning that is consistent with their meaning in the context of the relevant art and may not be interpreted in an idealized or overly formal sense unless expressly so defined herein.

Hereinafter, a display device according to each aspect of the present disclosure will be described with reference to the accompanying drawings.

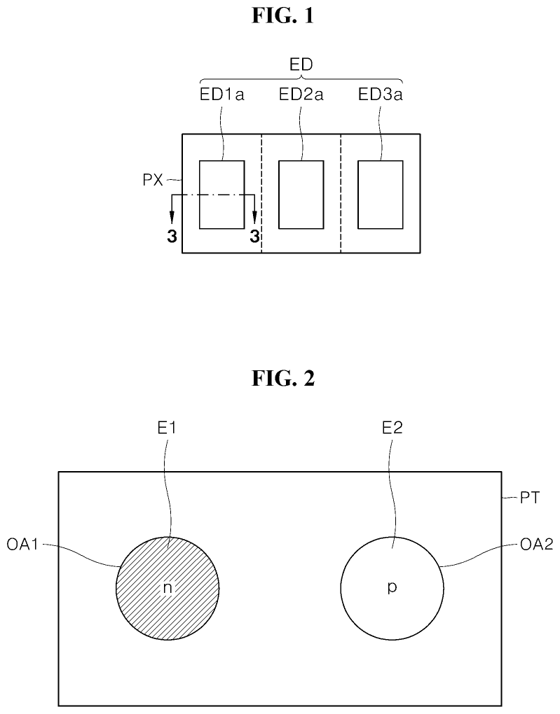

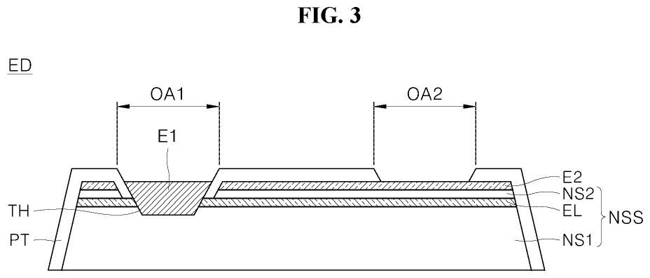

FIG. 1 is a plan view schematically illustrating a pixel of a display device according to an aspect of the present disclosure. FIG. 2 and FIG. 3 are diagrams showing a light-emitting element according to one aspect of the present disclosure. FIG. 2 is a top view showing the light-emitting element. FIG. 3 is a cross-sectional view taken along line 3-3 in FIG. 1.

Referring to FIGS. 1 to 3, the display device according to an aspect of the present disclosure may include a plurality of pixels PX. FIG. 1 shows one pixel PX among the plurality of pixels of the display device.

Each of the plurality of pixels PX may include a plurality of sub-pixels. Each of the sub-pixels may include a light-emitting area and a circuit area for driving the light-emitting area. The light-emitting area may include a plurality of main light-emitting element ED. The plurality of main light-emitting element ED may include at least one main light-emitting element disposed in each of the plurality of sub-pixels. For example, the main light-emitting element ED may include a red main light-emitting element, a green main light-emitting element, or a blue main light-emitting element that emits red (R), green (G), or blue (B) light, respectively. However, the present disclosure is not limited thereto. For example, each of the pixels P may further include a white pixel. In addition, the main light-emitting element ED may further include white main light-emitting element, magenta main light-emitting element, yellow main light-emitting element and cyan main light-emitting element, or other combination of main light-emitting element.

The pixel PX of the display device according to one exemplary aspect of the present disclosure may include only the main light-emitting element ED without redundant light-emitting element. For example, the repair process for repairing the main light-emitting element ED is easily performed in the repair method of the display device according to an exemplary aspect of the present disclosure, such that the redundant light-emitting element is not disposed in the display device. The main light-emitting element ED also be referred to as a light-emitting element ED. A description thereof will be made later. Alternatively, the pixel PX of the display device according to one exemplary aspect of the present disclosure may include both the main light-emitting element ED and redundant light-emitting element.

Referring to FIG. 2 and FIG. 3, the light-emitting element ED according to an exemplary aspect of the present disclosure may at least include a nitride semiconductor structure NSS, a second electrode E2 disposed on the nitride semiconductor structure NSS, a passivation pattern PT and a first electrode E1. The nitride semiconductor structure NSS may at least include a first semiconductor layer NS1, an active layer EL, and a second semiconductor layer NS2. The second electrode E2 may be disposed on the upper surface (e.g., uppermost surface) of the nitride semiconductor structure NSS. The nitride semiconductor structure NSS may have a trench hole TH extending through the second semiconductor layer NS2 and the active layer EL to expose a portion of a surface of the first semiconductor layer NS1 on one side of the nitride semiconductor structure NSS.

The first semiconductor layer NS1 may be a layer for supplying electrons to the active layer EL, and may include a nitride-based semiconductor including first conductivity-type impurities. For example, the first conductivity-type impurity may include an N-type impurity, and the n-type impurity, for example, may be silicon (Si), germanium, or tin (Sn), but is not limited thereto. The active layer EL may be disposed on the first semiconductor layer NS1 and function as a layer for emitting light, and may include a single or multi-quantum well (MQW) structure having a well layer and a barrier layer having a higher band gap than that of the well layer. The active layer EL may be formed of, for example, a nitride semiconductor such as indium gallium nitride (InGaN) and gallium nitride (GaN), but is not limited thereto.

The second semiconductor layer NS2 may be disposed on the active layer EL and function as a layer for injecting holes into the active layer EL. The second semiconductor layer NS2 may include a nitride-based semiconductor including second conductivity type impurities. For example, the second conductivity type impurity may include a P type impurity, the p-type impurity, for example, may be magnesium, zinc (Zn), or beryllium (Be), but is not limited thereto. The active layer EL may emit light based on a combination of electrons and holes respectively supplied from the first semiconductor layer NS1 and the second semiconductor layer NS2.

The first electrode E1 and the second electrode E2 may be respectively exposed through circular open areas OA1 and OA2 in a top view to improve detection performance of the lighting inspection which inspects whether the light-emitting element ED is defective. The first electrode E1 may be connected to a portion of the first semiconductor layer NS1 exposed through the trench hole TH and may be coplanar with the second electrode E2. Accordingly, a tool for the lighting inspection may be easily connected to the first electrode E1, which will improve the convenience of lighting inspection.

The passivation pattern PT may at least cover an outer surface of the nitride semiconductor structure NSS and the second electrode E2. The passivation pattern PT may have the first open area OA1 defined therein exposing a portion of a surface of the first electrode E1 and the second open area OA2 defined therein exposing a portion of a surface of the second electrode E2. The first electrode E1 may be connected to a portion of the first semiconductor layer NS exposed through the trench hole TH, and the second electrode E2 may be connected to the second semiconductor layer NS2. The first electrode E1 and the second electrode E2 may be spaced apart from each other and may be electrically insulated from each other via the passivation pattern PT. Each of the first electrode E1 and the second electrode E2 may comprise a metal material such as Au, W, Pt, Si, Ir, Ag, Cu, Ni, Ti, and Cr, and an alloy thereof. Alternatively, each of the first electrode E1 and the second electrode E2 may include a transparent conductive material such as ITO indium tin oxide and IZO indium zinc oxide. The light-emitting element ED according to an exemplary aspect of the present disclosure may have a lateral shape. The light-emitting element ED according to an exemplary aspect of the present disclosure may be embodied as a micro-LED. The micro-LED may refer to an LED made of an inorganic material and may be a light-emitting element of 100 μm or smaller.

In a process of transferring the light-emitting element ED onto the panel substrate, the lighting inspection and the repair process may be performed. This will be described with reference to the drawings below.

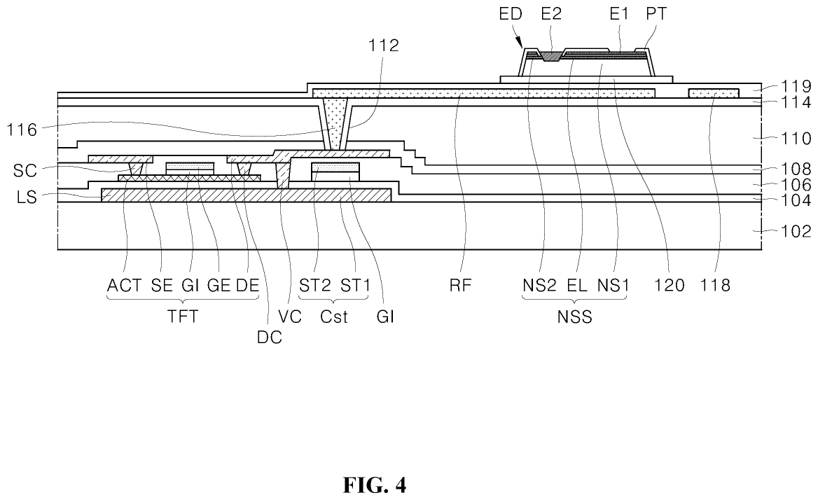

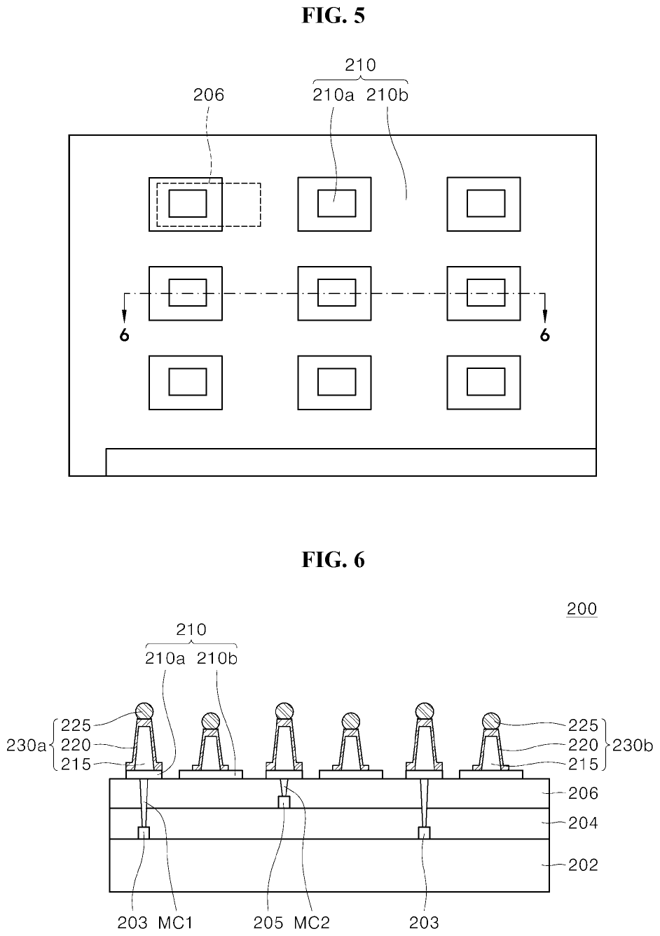

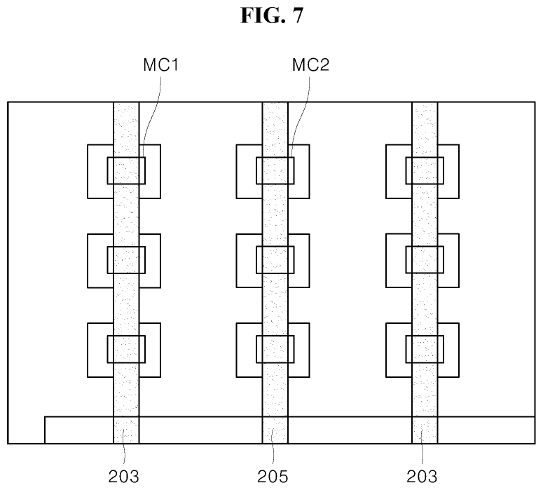

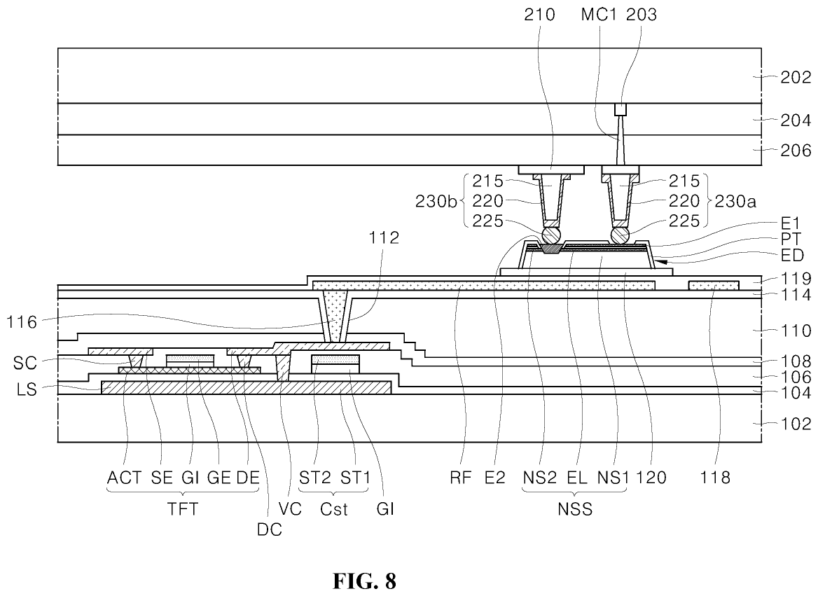

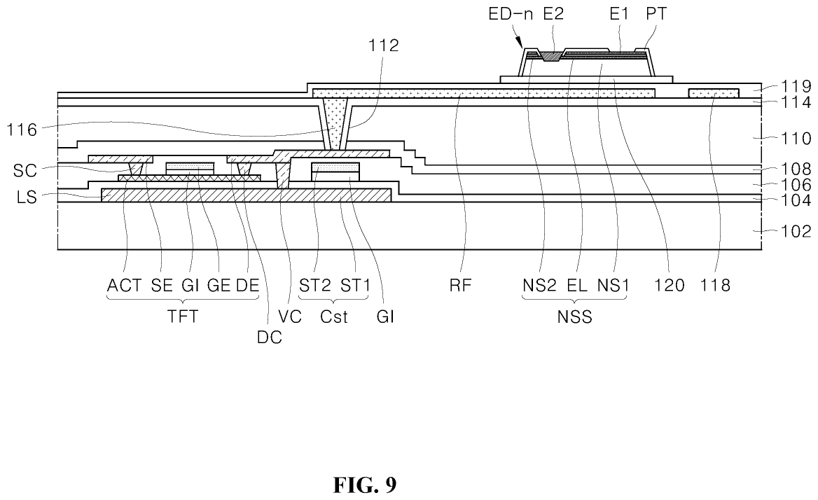

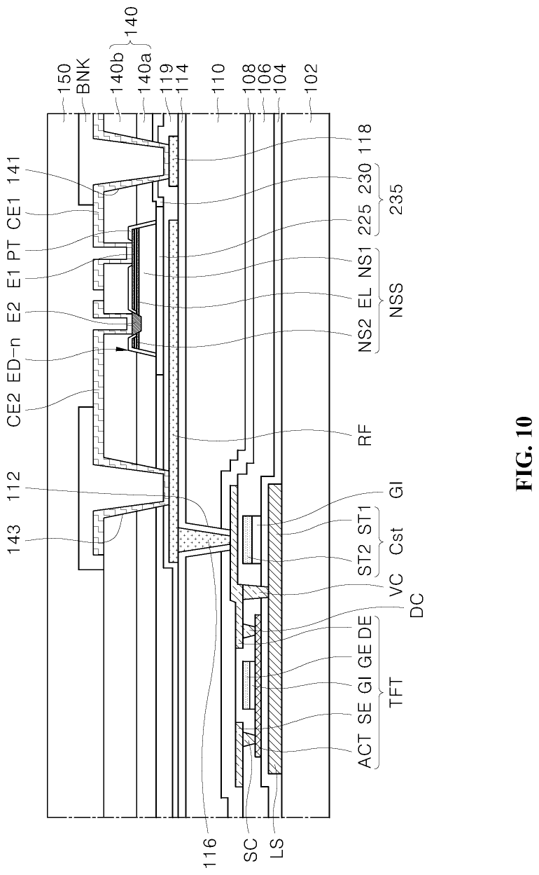

FIGS. 4 to 10 are diagrams illustrating a method of repairing a display device according to one exemplary aspect of the present disclosure.

Referring to FIG. 4, a panel substrate 100 including an adhesive pattern 120 applied thereon is prepared, and the plurality of light-emitting element ED is transferred onto the adhesive pattern 120. FIG. 4 shows the light-emitting element and a thin-film transistor disposed in one sub-pixel for convenience of illustration. The sub-pixels may have the same or substantially same structure.

A light-blocking layer LS may be disposed on a base substrate 102 of the panel substrate 100. The light-blocking layer LS may prevent or at least reduce light incident from a position under the base substrate 102 from invading an active layer of each of a plurality of thin-film transistors to reduce leakage current. For example, the light-blocking layer LS may be disposed under the active layer ACT of the thin-film transistor TFT functioning as a driving transistor to prevent or at least reduce the light from being incident to the active layer ACT. The light-blocking layer LS may include a light-blocking material. For example, the light-blocking layer LS may include a black dye.

A buffer layer 104 is disposed on the light-blocking layer LS. The buffer layer 104 may block impurities or moisture flowing through the base substrate 102. The buffer layer 104 may include, for example, an insulating material such as silicon oxide (SiOx) and silicon nitride (SiNx). In particular, the buffer layer 104 may be composed of a single layer or multiple layers of silicon oxide SiOx or silicon nitride SiNx, but not limited thereto. However, the buffer layer 104 may be omitted depending on the type of the substrate 102 or the type of transistor, but not limited thereto.

The thin-film transistor TFT is disposed on the buffer layer 104. The thin-film transistor TFT may include the active layer ACT, a gate electrode GE, a source electrode SE, and a drain electrode DE. A gate insulating layer GI may be disposed between the active layer ACT and the gate electrode GE.

The active layer ACT may include an active area overlapping with the gate electrode GE to constitute a channel, and a source area and a drain area located respectively on both opposing sides of the active area. In particular, the active layer ACT may be formed of a semiconductor material such as oxide semiconductor, amorphous silicon, or polycrystalline semiconductor, but not limited thereto. The polycrystalline semiconductor may be formed of a low temperature poly silicon (LTPS) having a high mobility, but is not limited thereto. In addition, the active layer ACT may be formed of an oxide semiconductor or includes the oxide semiconductor, for example, the active layer ACT may be formed of one of indium gallium zinc oxide (IGZO), indium zinc oxide (IZO), indium gallium tin oxide (IGTO), and indium gallium oxide (IGO), but is not limited thereto. Alternatively, the active layer ACT may be formed of various organic semiconductors such as amorphous silicon (a-Si), polycrystalline silicon (poly-Si), or pentacene, etc., but is not limited thereto. A first interlayer insulating film 106 is disposed on the gate electrode GE. The first interlayer insulating film 106 may receive a source contact SC and a drain contact DC therein. The source contact SC and the drain contact DC may contact portions of surfaces of the source area and the drain area of the active layer ACT, respectively. The source contact SC and the drain contact DC may be respectively electrically connected to the source electrode SE and the drain electrode DE located on the first interlayer insulating film 106. Thus, the source electrode SE and the drain electrode DE may be respectively electrically connected to the source and drain areas of the active layer ACT via the source contact SC and the drain contact DC.

The gate insulating layer GI may be formed on the active layer ACT. The gate insulating layer GI is an insulating layer for insulating the active layer ACT and the gate electrode GE from each other, and may be composed of a single layer or multilayers of silicon oxide SiOx or silicon nitride SiNx, but not limited thereto. the gate electrode GE may be formed on the gate insulating layer GI, the gate electrode GE may be formed of a conductive material, for example, copper Cu, aluminum Al, molybdenum Mo, nickel Ni, titanium Ti, chromium Cr, or an alloy thereof, but not limited thereto.

The storage capacitor Cst may include a first capacitor electrode ST1 and a second capacitor electrode ST2. The first capacitor electrode ST1 may be disposed between the base substrate 102 and the buffer layer 104. The first capacitor electrode ST1 may be formed integrally with the light-blocking layer LS. The buffer layer 104 and the gate insulating layer GI may be disposed on the first capacitor electrode ST1 and may act as a dielectric layer. The second capacitor electrode ST2 may be disposed on the gate insulating layer GI. The second capacitor electrode ST2 may be made of the same or substantially same material as that of the gate electrode GE (for example, copper Cu, aluminum Al, molybdenum Mo, nickel Ni, titanium Ti, chromium Cr, or an alloy thereof).

A first passivation layer 108 is disposed on the source electrode SE and the drain electrode DE. The first passivation layer 108 serves to protect the thin-film transistor TFT and the storage capacitor Cst, and may include an insulating material. For example, the passivation layer 108, which is a kind of dielectric (e.g., an inorganic dielectric), may be constituted by a single layer made of a silicon oxide (SiOx) film, a silicon nitride (SiNx) film, or a silicon oxynitride (SiOxNy) film or a multilayer film thereof, etc. A first planarization layer 110 is disposed on the first passivation layer 108. The first planarization layer 110 serves to remove a surface step caused by an underlying component such as the thin-film transistor TFT. The first planarization layer 110 may include a photoactive compound (PAC). However, the present disclosure is not limited thereto.

The first planarization layer 110 may be provided on the passivation layer 108 and have a contact-hole 112 defined therein exposing a portion of a surface of the drain electrode DE. Depending on circumstances, the passivation layer 108 may be omitted when the first planarization layer 110 has a function of protecting the thin film transistor TFT. For example, the first planarization layer 110, which may be a kind of inorganic or organic dielectric, may be made of one of photo acrylic, polyimide, benzocyclobutene resin, and acrylate, etc. Depending on circumstances, the overcoat layer 150 may be formed to have a single layer or a multilayer structure. A second interlayer insulating film 114 may be disposed on and along a side surface of the contact-hole 112 and on the first planarization layer 110. A via contact 116 fills the contact-hole 112. The drain electrode DE contacting a bottom surface of the via contact 116 may be electrically connected to the light-blocking layer LS via a through-electrode VC extending through the first interlayer insulating film 106 and the buffer layer 104.

A reflective electrode RF may be disposed on the via contact 116 and the second interlayer insulating film 114. The reflective electrode RF reflects the light emitted from the light-emitting element toward the panel substrate 100 to direct the light emitted from the light-emitting element to an outside out of the display area. The reflective electrode RF may include a metal material with high reflectivity. For example, the metal material with high reflectivity may have a single-layer structure or a stack structure made of one material selected from aluminum (Al), copper (Cu), silver (Ag), molybdenum (Mo), gold (Au), magnesium (Mg), calcium (Ca), or barium (Ba), or an alloy of at least two thereof. A bottom surface of the reflective electrode RF may be electrically connected to the drain electrode DE via the via contact 116.

A signal line 118 may be disposed on the second interlayer insulating film 114 to be coplanar with the reflective electrode RF. The signal line 118 may include a plurality of signal lines. The plurality of signal lines may include a high-potential voltage line VDDL, a low-potential voltage line VSSL, a reference voltage line RL, a data line DL, and a scan line SL. A second passivation layer 119 may be disposed to cover the reflective electrode RF.

The adhesive pattern 120 may be disposed on the second passivation layer 119. The adhesive pattern 120 may include a material whose adhesive strength is removed when UV is irradiated thereto. Then, the light-emitting element ED may be placed on the adhesive pattern 120 in a transfer process. The transfer process may proceed using, for example, a stamping scheme.

The lighting inspection on the light-emitting element ED may be performed immediately after transferring the light-emitting element ED onto the adhesive pattern 120. For the lighting inspection, an inspection substrate 200 on which an inspecting contact member is disposed at a position corresponding to a position of the light-emitting element ED disposed on the panel substrate 100 to be inspected is prepared. Hereinafter, a description thereof will be made with reference to FIGS. 5 to 8.

Referring to FIG. 5 to FIG. 8, the inspection substrate 200 is provided. To this end, first metal patterns 203 extending in a line shape along one direction are formed on a glass substrate 202. The first metal patterns 203 as line-shaped patterns may be spaced apart from each other by a predetermined distance (see FIG. 7). Next, a first inspecting passivation layer 204 covering the first metal pattern 203 is formed. The first inspecting passivation layer 204 may include an insulating material (for example, Polyethylene terephthalate (PET), Polyethylene naphthalate (PEN), Poly(methyl methacrylate) (PMMA), Cyclo-olefin polymers (COP) or cyclo-olefin copolymers (COC)).

A second metal pattern 205 may be disposed on the first inspecting passivation layer 204. The second metal pattern 205 may have a line shape extending along one direction of the inspection substrate 200 (shown in FIG. 7). Accordingly, the second metal pattern 205 and the first metal pattern 203 (for example, copper Cu, aluminum Al, molybdenum Mo, nickel Ni, titanium Ti, chromium Cr, or an alloy thereof) may be disposed in different layers. Further, the second metal pattern 205 may not overlap with the first metal pattern 203. For example, referring to FIG. 7, the first metal patterns 203 and the second metal patterns 205 may be alternately arranged with each other while being disposed at different layers. But aspects of the present disclosure are not limited thereto.

A second inspecting passivation layer 206 may be disposed to cover the second metal pattern 205. The second inspecting passivation layer 206 may include an insulating material same or similar to the first inspecting passivation layer 204. Third metal patterns 210 may be disposed on the second inspecting passivation layer 206. Referring to FIG. 5, the third metal pattern 210 may include a first plate pattern 210a and a second plate pattern 210b. A surface of the second inspecting passivation layer 206 may be exposed in a rectangular ring shape to define an island shape. Each of the first plate pattern 210a and the second plate pattern 210b may disposed in the island shape. But aspects of the present disclosure are not limited thereto. According to an example aspect of the present disclosure, the island shape may have a rectangular shape, a circular shape, an ellipse or oval shape, or a quadrilateral shape, but aspects of the present disclosure are not limited thereto.

Each of some of the first plate patterns 210a of the third metal pattern 210 may be electrically connected to the first metal pattern 203 via a first interlayer wiring electrode MC1. Further, the first plate pattern 210a between adjacent ones of the some of the first plate patterns 210a of the third metal pattern 210 may be connected to the second metal pattern 205 via a second interlayer wiring electrode MC2. The first interlayer wiring electrode MC1 may extend through the second inspecting passivation layer 206 and the first inspecting passivation layer 204 to be connected to a surface of the first metal pattern 203. The second interlayer wiring electrode MC2 may extend through the second inspecting passivation layer 206 to be connected to a surface of the second metal pattern 205.

FIG. 6 is a cross-sectional view taken along line 6-6 in FIG. 5. As shown in FIG. 6, inspecting contact units 230a and 230b may be disposed on the first plate pattern 210a and the second plate pattern 210b of the third metal pattern 210, respectively. Each of the inspecting contact units 230a and 230b may include a protrusion pattern 215. The protrusion pattern 215 may include the photoactive compound (PAC). Cross section of the protrusion pattern 215 may have a taper shape in which a width of an upper surface thereof is smaller than a width of a bottom surface thereof. But aspects of the present disclosure are not limited thereto, for example, cross section of the protrusion pattern 215 may be truncated cone.

An outer surface of the protrusion pattern 215 may be covered with a fourth metal pattern 220. The fourth metal pattern 220 may be disposed to be in contact with a top surface of each of the first plate pattern 210a and the second plate pattern 210b at a bottom thereof while surrounding the outer surface of the protrusion pattern 215. A contact pin 225 is disposed on an upper surface of the protrusion pattern 215 to be connected to the fourth metal pattern 220. The contact pin 225 may have a spherical shape. However, the present disclosure is not limited thereto, for example, the contact pin 225 may have hemisphere, cylinder-shaped, etc. The contact pin 225 may be made of a material including indium. But aspects of the present disclosure are not limited thereto.

The inspecting contact units 230a and 230b may include the first inspecting contact unit 230a having a first height and the second inspecting contact unit 230b having a second height smaller than the first height. A common voltage as a positive voltage of a first polarity may be applied to the second inspecting contact unit 230b disposed on the second plate pattern 210b. In addition, a cathode voltage as a negative voltage with a second polarity opposite to the first polarity may be applied to the first inspecting contact unit 230a disposed on each of both opposing sides of the second inspecting contact unit 230b. Alternatively, a common voltage as a positive voltage of a first polarity may be applied to the first inspecting contact unit 230a disposed on the first plate pattern 210a. In addition, a cathode voltage as a negative voltage with a second polarity opposite to the first polarity may be applied to and the second inspecting contact unit 230b disposed on each of both opposing sides of the first inspecting contact unit 230a.

Referring to FIG. 8, the inspection substrate 200 including the inspecting contact units 230a and 230b is placed on top of the light-emitting element ED disposed on the panel substrate 100. Then, the contact pins 225 of the inspecting contact units 230a and 230b are connected to the light-emitting element ED. In this regard, the contact pin 225 of the first inspecting contact unit 230a may be connected to the first electrode E1, while the contact pin 225 of the second inspecting contact unit 230b may be connected to the second electrode E2.

Subsequently, the lighting inspection is performed by applying a voltage to the inspecting contact units 230a and 230b. In the lighting inspection, the common voltage as the positive voltage may be applied to the second inspecting contact unit 230b via which the first electrode E2 is driven, while the cathode voltage as the negative voltage may be applied to the first inspecting contact unit 230a via which the second electrode E1 is driven, Thus, whether or not lighting occurs from the light-emitting element ED is identified, and thus whether the light-emitting element is defective is identified. The defective light-emitting element may be caused from a defective product occurring in the manufacturing of the light-emitting element, or may be caused by a transfer failure in which the light-emitting element is not transferred to a target location on the panel substrate.

The light-emitting element ED which is determined to be the defective light-emitting element based on the result of the lighting inspection may be subjected to ultraviolet (UV) irradiation thereto, such that a bonding force between the adhesive pattern 120 and the defective light-emitting element may be removed. Then, a repair process is performed. The repair process may proceed by removing the defective light-emitting element and replacing with the normal light-emitting element. Thus, as shown in FIG. 9, the defective light-emitting element may be replaced with a normal light-emitting element ED-n.

Next, referring to FIG. 10, the normal light-emitting element ED-n may be covered with an upper planarization layer 140. The upper planarization layer 140 may have a thickness sufficient to planarize an upper surface having a step caused by the underlying circuit element. The upper planarization layer 140 may include a structure in which a second planarization layer 140a and a third planarization layer 140b are stacked. The upper planarization layer 140 may have openings 141 and 143 defined therein exposing portions of surfaces of the signal line 118 and the reflective electrode RF, respectively.

The openings 141 and 143 may include the first opening 141 extending through the upper planarization layer 140 to expose the portion of the surface of the signal line 118 and the second opening 143 extending through the upper planarization layer 140 to expose the portion of the surface of the reflective electrode RF. Further, the upper planarization layer 140 may not cover a portion of an upper surface of each of the first electrode E1 and the second electrode E2 of the normal light-emitting element ED-n to be exposed. Thus, the exposed first electrode E1 and the second electrode E2 may be electrically connected to a first wiring electrode CE1 and a second wiring electrode CE2, respectively.

The first wiring electrode CE1 may extend along and on an exposed surface of the first opening 141, and the second wiring electrode CE2 may extend along and on an exposed surface of the second opening 143. The first wiring electrode CE1 may be electrically connected to the signal line 118 and first electrode E1. The second wiring electrode CE2 may be electrically connected to the second electrode E2 and the drain electrode DE via the reflective electrode RF. But aspects of the present disclosure are not limited thereto.

The first wiring electrode CE1 and the second wiring electrode CE2 may be disposed on the same layer and made of the same or substantially same conductive material. In one example, each of the first wiring electrode CE1 and the second wiring electrode CE2 may include a transparent metal oxide such as indium-tin-oxide (ITO), or indium-zinc-oxide (IZO).

A bank BNK may be disposed on the upper planarization layer 140. The bank BNK may be made of an opaque material. The bank BNK serves to define a sub-pixel. Thus, the bank BNK may be made of an insulating material containing a black material. The bank BNK may be made of, for example, a transparent carbon-based mixture. Specifically, the bank BNK may contain carbon black, but is not limited thereto. The bank may also be made of a transparent insulating material. However, the present disclosure is not limited thereto. The first opening 141 and the second opening 143 may be filled with a material constituting the bank BNK. Further, the bank BNK may be positioned in an area around the normal light-emitting element ED-n except for an area where the normal light-emitting element ED-n is disposed. A protective layer 150 may be disposed on the upper planarization layer 140 on which the bank BNK has been formed. The protective layer 150 may prevent or at least reduce impurities from flowing into the normal light-emitting element ED-n.

Conventionally, the lighting inspection on the light-emitting element is performed after transferring the light-emitting element onto the panel substrate and performing the line connection process to the light-emitting element. Thus, it is difficult to repair the light-emitting element. Due to the difficulty in repairing the light-emitting element, a redundancy structure in which a redundant light-emitting element emitting light of the same or substantially same color as a color of light emitted from the main light-emitting element is present is applied. However, there is a limitation in that a manufacturing cost increases because a plurality of redundant light-emitting elements are disposed even when no defect occurs in the main light-emitting element.

In this regard, in the repair method according to one aspect of the present disclosure, the lighting inspection is performed immediately after transferring the light-emitting element ED onto the adhesive pattern 120 and may identify whether the light-emitting element is defective. Then, upon determination that the light-emitting element ED is defective, the repair process thereon may be performed. Thus, the repair process of the light-emitting element becomes easy, such that the redundant light-emitting element that accounts for a significant portion of the manufacturing cost may be omitted, thereby reducing a production energy.

Although the aspects of the present disclosure have been described in more detail with reference to the accompanying drawings, the present disclosure is not necessarily limited to these aspects, and may be modified in a various manner within the scope of the technical idea of the present disclosure. Accordingly, the aspects as disclosed in the present disclosure are intended to describe rather than limit the technical idea of the present disclosure, and the scope of the technical idea of the present disclosure is not limited by these aspects. Therefore, it should be understood that the aspects described above are not restrictive but illustrative in all respects.

A method for repairing a display device which includes a panel substrate, according to various aspects of the present disclosure, may include: transferring a plurality of light-emitting element onto a panel substrate: preparing an inspection substrate having a plurality of inspecting contact units each including contact pins: positioning the inspection substrate on the panel substrate such that the contact pins of the inspection substrate face the plurality of light-emitting element: determining whether the light-emitting element is defective by connecting the contact pins to the plurality of light-emitting element; and repairing the defective light-emitting element to a normal light-emitting element.

According to some example aspects of the present disclosure, the light-emitting element may include: a nitride semiconductor structure including a first semiconductor layer, an active layer disposed on the first semiconductor layer, and a second semiconductor layer disposed on the active layer: a passivation pattern disposed on an outer surface of the nitride semiconductor structure: a first electrode connected to the first semiconductor layer; and a second electrode connected to the second semiconductor layer.

According to some example aspects of the present disclosure, the first electrode may be formed to be coplanar with the second electrode.

According to some example aspects of the present disclosure, preparing the inspection substrate may include: preparing the inspection substrate may include: providing a glass substrate: forming first metal patterns disposed on the glass substrate and extending in a line shape: forming a first inspecting passivation layer covering the first metal patterns; forming second metal patterns disposed on the first inspecting passivation layer: forming a second inspecting passivation layer covering the second metal patterns: forming third metal patterns on the second inspecting passivation layer, wherein the third metal patterns may include first and second plate patterns, wherein the first and second plate patterns are spaced apart from each other; and forming the inspecting contact units including a first inspecting contact unit and a second inspecting contact units, wherein the first inspecting contact unit may be disposed on the first plate pattern and include the contact pin connected to one electrode of the light-emitting element, wherein the second inspecting contact unit may be disposed on the second plate pattern and include the contact pin connected to the other electrode of the light-emitting element.

According to some example aspects of the present disclosure, each of the first and second inspecting contact unit may include protrusion pattern, fourth metal pattern covering the protrusion pattern and contact pin disposed on an upper surface of the protrusion pattern.

According to some example aspects of the present disclosure, the protrusion pattern may be of a taper shape in which a width of an upper surface thereof is smaller than a width of a bottom surface thereof.

According to some example aspects of the present disclosure, wherein each first plate pattern may have an island shape surrounded with the second inspecting passivation layer, wherein each second plate pattern may have an island shape surrounded with the second inspecting passivation layer.

According to some example aspects of the present disclosure, the first metal pattern and the second metal pattern may be disposed in different layers and may not overlap with each other.

According to some example aspects of the present disclosure, the first metal patterns and the second metal patterns may be disposed in different layers without overlapping with each other and are alternately arranged with each other.

According to some example aspects of the present disclosure, wherein determining whether the light-emitting element is defective may include, applying a voltage to the contact pins to identify whether the light-emitting element is turned on.

According to some example aspects of the present disclosure, wherein repairing the defective the light-emitting element may include, removing the light-emitting element determined to be defective and replacing with the normal light-emitting element.

According to some example aspects of the present disclosure, a voltage having a first polarity may be applied to the first inspecting contact unit, while a voltage having a second polarity different from the first polarity may be applied to the second inspecting contact unit.

According to some example aspects of the present disclosure, the first electrode or the second electrode may have a circular shape in a top view thereof.

A method for inspecting a display device during manufacturing process of the display device, according to various aspects of the present disclosure, wherein the display device may include a panel substrate, may include: transferring a plurality of light-emitting element onto the panel substrate: positioning the inspection substrate on the panel substrate such that contact pins of the inspection substrate face the plurality of light-emitting element; and determining whether the light-emitting element is defective by connecting the contact pins to the plurality of light-emitting element.

It will be apparent to those skilled in the art that various modifications and variations may be made in the present disclosure without departing from the technical idea or scope of the disclosures. Thus, it may be intended that aspects of the present disclosure cover the modifications and variations of the disclosure provided they come within the scope of the appended claims and their equivalents.

What is claimed is:

1. A method for repairing a display device, the method comprising:
transferring a plurality of light-emitting elements onto a panel substrate;
preparing an inspection substrate having a plurality of inspecting contact units each including contact pins;
positioning the inspection substrate on the panel substrate such that the contact pins of the inspection substrate face the plurality of light-emitting elements;
determining whether the plurality of light-emitting elements is defective by connecting the contact pins to the plurality of light-emitting elements; and
repairing a defective light-emitting element to a normal light-emitting element.

2. The method of claim 1, wherein the plurality of light-emitting elements includes:
a nitride semiconductor structure including a first semiconductor layer, an active layer disposed on the first semiconductor layer, and a second semiconductor layer disposed on the active layer;
a passivation pattern disposed on an outer surface of the nitride semiconductor structure;
a first electrode connected to the first semiconductor layer; and
a second electrode connected to the second semiconductor layer.

3. The method of claim 2, wherein the first electrode is coplanar with the second electrode.

4. The method of claim 1, wherein preparing the inspection substrate includes:
providing a glass substrate;
forming first metal patterns disposed on the glass substrate and extending in a line shape;
forming a first inspecting passivation layer covering the first metal patterns;
forming second metal patterns disposed on the first inspecting passivation layer;
forming a second inspecting passivation layer covering the second metal patterns;
forming third metal patterns on the second inspecting passivation layer, wherein the third metal patterns include first and second plate patterns that are spaced apart from each other; and
forming the plurality of inspecting contact units including a first inspecting contact unit and a second inspecting contact unit,
wherein the first inspecting contact unit is disposed on the first plate pattern and includes the contact pins connected to one electrode of the plurality of light-emitting elements, and
wherein the second inspecting contact unit is disposed on the second plate pattern and includes the contact pins connected to another electrode of the plurality of light-emitting elements.

5. The method of claim 4, wherein each of the first and second inspecting contact unit includes protrusion pattern, fourth metal pattern covering the protrusion pattern and the contact pins disposed on an upper surface of the protrusion pattern.

6. The method of claim 5, wherein the protrusion pattern has a taper shape in which a width of an upper surface thereof is smaller than a width of a bottom surface thereof.

7. The method of claim 3, wherein each first plate pattern has an island shape surrounded with the second inspecting passivation layer, and
wherein each second plate pattern has an island shape surrounded with the second inspecting passivation layer.

8. The method of claim 3, wherein the first metal pattern and the second metal pattern are disposed in different layers and do not overlap with each other.

9. The method of claim 3, wherein the first metal patterns and the second metal patterns are disposed in different layers without overlapping with each other and are alternately arranged with each other.

10. The method of claim 1, wherein the determining whether the plurality of light-emitting elements is defective includes applying a voltage to the contact pins of the inspection contact unit to identify whether the plurality of light-emitting elements is turned on.

11. The method of claim 1, wherein the repairing the defective light-emitting element includes removing the defective light-emitting element and replacing with the normal light-emitting element.

12. The method of claim 3, wherein the first inspecting contact unit receives a voltage having a first polarity and the second inspecting contact unit receives a voltage having a second polarity different from the first polarity.

13. The method of claim 2, wherein the first electrode or the second electrode has a circular shape in a top view thereof.

14. A method for inspecting a display device during manufacturing process of the display device, wherein the display device comprises a panel substrate, the method comprising:
transferring a plurality of light-emitting elements onto the panel substrate;
positioning an inspection substrate on the panel substrate such that contact pins of the inspection substrate face the plurality of light-emitting elements; and
determining whether the plurality of light-emitting elements is defective by connecting the contact pins to the plurality of light-emitting elements.
